(19) United States
(12) Patent Application Publication
(10) Pub. No.: US 2024/0282900 A1
(43) Pub. Date: Aug. 22, 2024

(54) CIRCUIT SUBSTRATE AND MANUFACTURING METHOD AND DETECTION METHOD THEREFOR, AND ELECTRONIC APPARATUS

(71) Applicants: BOE MLED Technology Co., Ltd., Beijing (CN); BOE TECHNOLOGY GROUP CO., LTD., Beijing (CN)

(72) Inventors: Shubai ZHANG, Beijing (CN); Lingyun SHI, Beijing (CN); Wei ZHANG, Beijing (CN); Longtao HUANG, Beijing (CN); Zhaohui LI, Beijing (CN); Zhifu YANG, Beijing (CN); Hao CHENG, Beijing (CN)

(73) Assignees: BOE MLED Technology Co., Ltd., Beijing (CN); BOE TECHNOLOGY GROUP CO., LTD., Beijing (CN)

(21) Appl. No.: 18/649,385

(22) Filed: Apr. 29, 2024

Related U.S. Application Data
(63) Continuation of application No. PCT/CN2023/070173, filed on Jan. 3, 2023.

(51) Int. Cl. H01L 33/62; G06T 7/00; H01L 33/58

(52) U.S. Cl. CPC H01L 33/62; G06T 7/0004; H01L 33/58; G06T 2207/30121; G06T 2207/30152; H01L 2933/0066

(57) ABSTRACT

A circuit substrate includes a base substrate, traces, a protective layer, and an electronic device. The traces are provided on the base substrate. The protective layer is provided on the traces, and has openings each exposing a portion of a trace, the portion serving as a conductive pattern. The electronic device includes a chip and multiple bumps provided on the chip. The conductive pattern is connected to at least one of the bumps on the chip. The conductive pattern includes a first portion and a second portion connected to each other. An orthographic projection of the chip on the base substrate covers an orthographic projection of the first portion on the base substrate, and is non-overlapping with an orthographic projection of the second portion on the base substrate. The total area of conductive patterns connected to the chip is less than an area of the chip.

### CROSS-REFERENCE TO RELATED APPLICATION

This application is a Bypass Continuation Application of International Patent Application No. PCT/CN2023/070173 filed on Jan. 3, 2023, which is incorporated herein by reference in its entirety.

### TECHNICAL FIELD

The present disclosure relates to the field of display technologies, and in particular, to a circuit substrate, manufacturing and detection methods therefor, and an electronic apparatus.

### BACKGROUND

Electronic apparatuses, e.g., cell phones and computers, usually have a function to display images. For example, an electronic apparatus may include a liquid crystal display (LCD) panel, and a light-emitting substrate that is also referred to as a backlight substrate or a light panel for backlight. The light-emitting substrate is provided on the back side of the LCD panel to provide a backlight therefor. The LCD panel realizes the display of an image by adjusting the transmittance of light rays of each sub-pixel.

The light-emitting substrate may include numerous light-emitting elements, such as mini light-emitting diodes (Mini LEDs).

### SUMMARY

In a first aspect, a circuit substrate is provided. The circuit substrate includes a base substrate, a plurality of traces, a protective layer, and an electronic device. The plurality of traces is provided on the base substrate. The protective layer is provided on the plurality of traces, the protective layer having a plurality of openings each exposing a portion of a trace, the portion serving as a conductive pattern. The electronic device includes a chip and multiple bumps provided on the chip. The conductive pattern is connected to at least one of the bumps on the chip; the conductive pattern includes a first portion and a second portion connected to each other; an orthographic projection of the chip on the base substrate covers an orthographic projection of the first portion on the base substrate, and is non-overlapping with an orthographic projection of the second portion on the base substrate; and a total area of multiple conductive patterns connected to the chip is less than an area of the chip.

In some embodiments, the conductive pattern includes a body portion and at least one extension portion. The body portion has a first edge. The at least one extension portion protrudes the body portion from the first edge, where an extension portion has a first dimension less than a length of the first edge, the first dimension of the extension portion being a dimension of the extension portion in a direction parallel to the first edge. The orthographic projection of the chip on the base substrate covers at least a portion of an orthographic projection of the body portion on the base substrate, and is non-overlapping with at least a portion of an orthographic projection of the extension portion on the base substrate.

In some embodiments, the first portion includes at least a portion of the body portion whose orthographic projection on the base substrate is covered by the orthographic projection of the chip on the base substrate; and the second portion includes at least a portion of the extension portion whose orthographic projection on the base substrate is non-overlapping with the orthographic projection of the chip on the base substrate.

In some embodiments, a total area of the at least one extension portion is less than an area of the body portion.

In some embodiments, the extension portion has a maximum second dimension greater than a dimension of the body portion in a direction perpendicular to the first edge, the second dimension of the extension portion being a dimension of the extension portion in the direction perpendicular to the first edge.

In some embodiments, the body portion is in a shape of a rectangle, with the first edge being a long side of the rectangle.

In some embodiments, along a protruding direction of the extension portion, the first dimension of the extension portion is same at all positions; or along the protruding direction of the extension portion, the first dimension of the extension portion increases and then decreases; or along the protruding direction of the extension portion, the first dimension of the extension portion decreases and then increases.

In some embodiments, the extension portion of the conductive pattern includes a first sub-portion and a second sub-portion, and the first sub-portion and the second sub-portion form axisymmetric figures, with a symmetry axis being a demarcation line between the first sub-portion and the second sub-portion, the demarcation line being parallel to the first edge.

In some embodiments, the total area of the multiple conductive patterns is less than a difference between the area of the chip and an area of a conductive pattern gap covered by the chip, the conductive pattern gap being a gap between adjacent body portions.

In some embodiments, two of the multiple conductive patterns connected to the chip are a first conductive pattern and a second conductive pattern; each extension portion of the first conductive pattern is located on a side, away from a body portion of the second conductive pattern, of a body portion of the first conductive pattern; and each extension portion of the second conductive pattern is located on a side, away from the body portion of the first conductive pattern, of the body portion of the second conductive pattern.

In some embodiments, the plurality of traces include a first trace and a second trace, the first trace and the second trace are provided therebetween with a trace gap that is covered by the chip. A first edge of a conductive pattern of the first trace is parallel to an extension direction of the trace gap, and/or a first edge of a conductive pattern of the second trace is parallel to the extension direction of the trace gap.

In some embodiments, a ratio of an area of a portion, exposed by the bumps, of the conductive pattern to a reference area is less than or equal to 10%, the reference area being an area of a portion, belonging to the second portion, of the at least one extension portion of the conductive pattern.

In a second aspect, another circuit substrate is provided. The circuit substrate includes a base substrate, a connection group, and an electronic device. The connection group is provided on the base substrate and includes multiple conductive patterns. The electronic device includes a chip and multiple bumps provided on the chip. A conductive pattern is connected to at least one of the bumps on the chip; the conductive pattern includes a first portion and a second portion connected to each other; an orthographic projection of the chip on the base substrate covers an orthographic projection of the first portion on the base substrate, and is non-overlapping with an orthographic projection of the second portion on the base substrate; and a total area of multiple conductive patterns connected to the chip is less than an area of the chip. The beneficial effects that can be achieved by this circuit substrate can be found in the beneficial effects of the circuit substrate below and will not be repeated herein.

In a third aspect, an electronic apparatus is provided. The electronic apparatus includes a circuit substrate as in any of the above embodiments. Accordingly, the beneficial effects that can be achieved thereof can be found in the beneficial effects of the circuit substrate below and will not be repeated herein.

In a fourth aspect, a manufacturing method for a circuit substrate is provided, including the following steps: forming a plurality of traces on a base substrate; forming a protective layer, the protective layer covering the plurality of traces and formed with a plurality of openings each exposing a portion of a trace, the portion serving as a conductive pattern; forming a solder flux layer on a side of a plurality of conductive patterns away from the base substrate; placing an electronic device on the solder flux layer, the electronic device including a chip and multiple bumps provided on the chip, such that the conductive pattern faces at least one of the bumps, where the conductive pattern includes a first portion and a second portion connected to each other; an orthographic projection of the chip on the base substrate covers an orthographic projection of the first portion on the base substrate, and is non-overlapping with an orthographic projection of the second portion on the base substrate; and a total area of multiple conductive patterns that are to be connected to the chip is less than an area of the chip; and performing heat treatment on the traces, the solder flux layer, and the electronic device to remove the solder flux layer, such that the at least one bump on the chip is connected to the conductive pattern.

By the manufacturing method for the circuit substrate, the circuit substrate described in the first aspect can be obtained. Accordingly, the beneficial effects that can be achieved of the manufacturing method can be found in the beneficial effects of the circuit substrate below and will not be repeated herein.

In some embodiments, the conductive pattern includes a body portion and at least one extension portion; the body portion has a first edge; the at least one extension portion protrudes the body portion from the first edge; and an extension portion has a first dimension less than a length of the first edge, the first dimension of the extension portion being a dimension of the extension portion in a direction parallel to the first edge. The orthographic projection of the chip on the base substrate covers at least a portion of an orthographic projection of the body portion on the base substrate, and is non-overlapping with at least a portion of an orthographic projection of the extension portion on the base substrate; and a ratio of a length of the first edge to a reference dimension is in a range of 1 to 1.3, inclusive, the reference dimension being a dimension of the bump of the electronic device in a direction parallel to the first edge before placing the electronic device on the solder flux layer.

In some embodiments, the manufacturing method further includes forming the bumps, using a solder material, on the chip to obtain the electronic device, the solder material including a plurality of solder particles. The first dimension of the extension portion is greater than or equal to twice an average diameter of the plurality of solder particles; or the first dimension of the extension portion is greater than or equal to twice a maximum diameter of the plurality of solder particles.

In a fifth aspect, a detection method for a circuit substrate, as provided in the first aspect, is provided. The detection method includes: capturing an image of the circuit substrate at a side of the electronic device away from the base substrate; and in a case where it is determined that a ratio of an area of a portion, exposed by the bumps, of the conductive pattern to a reference area is greater than a preset value, outputting information for indicating that the conductive pattern and the electronic device have a poor soldering therebetween, the reference area being an area of a portion, belonging to the second portion, of the at least one extension portion of the conductive pattern.

By the detection method for the circuit substrate, the circuit substrate described in the first aspect can be detected. Accordingly, the beneficial effects that can be achieved of the detection method can be found in the beneficial effects of the circuit substrate below and will not be repeated herein.

In some embodiments, a second dimension of the portion, belonging to the second portion, of the at least one extension portion of the conductive pattern is greater than or equal to a minimum detectable dimension, the second dimension being a dimension of the portion in a direction perpendicular to the first edge.

In a sixth aspect, a detection method for a circuit substrate, as provided in the second aspect, is provided. The detection method includes: capturing an image of the circuit substrate at a side of the electronic device away from the base substrate; and in a case where it is determined that a ratio of an area of a portion, exposed by the bumps, of the conductive pattern to a reference area is greater than a preset value, outputting information for indicating that the conductive pattern and the electronic device have a poor soldering therebetween, the reference area being an area of the second portion of the conductive pattern.

By the detection method for the circuit substrate, the circuit substrate described in the second aspect can be detected. Accordingly, the beneficial effects that can be achieved of the detection method can be found in the beneficial effects of the circuit substrate below and will not be repeated herein.

### BRIEF DESCRIPTION OF THE DRAWINGS

In order to describe technical solutions in the present disclosure more clearly, the accompanying drawings to be used in some embodiments of the present disclosure will be introduced briefly; however, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a partial top view of a light-emitting substrate provided in the related art;

FIG. 2 is a partial top view of a light-emitting substrate, in accordance with embodiments of the present disclosure;

FIG. 3 is a structural diagram of an electronic apparatus, in accordance with embodiments of the present disclosure;

FIG. 4 is a structural diagram of another electronic apparatus, in accordance with embodiments of the present disclosure;

FIG. 5 is a circuit diagram of a circuit substrate, in accordance with embodiments of the present disclosure;

FIG. 6 is a partial top view of a circuit substrate, in accordance with embodiments of the present disclosure;

FIG. 7 is a partial top view of a circuit substrate, in accordance with embodiments of the present disclosure;

FIG. 8 is a cross-sectional view taken along the section line B1-B2 of FIG. 7;

FIG. 9 is a partial top view of a circuit substrate, in accordance with embodiments of the present disclosure;

FIG. 10 is a structural diagram of a connection group, in accordance with embodiments of the present disclosure;

FIG. 11 is a diagram illustrating a structure formed by an electronic device that has a shift during soldering, in accordance with embodiments of the present disclosure;

FIG. 12 is a partial top view of a circuit substrate, in accordance with embodiments of the present disclosure;

FIG. 13 is a partial top view of another circuit substrate, in accordance with embodiments of the present disclosure;

FIG. 14 is a structural diagram of another connection group, in accordance with embodiments of the present disclosure;

FIG. 15 is a structural diagram of yet another connection group, in accordance with embodiments of the present disclosure;

FIG. 16 is a structural diagram of still another connection group, in accordance with embodiments of the present disclosure;

FIG. 17 is a structural diagram of still yet another connection group, in accordance with embodiments of the present disclosure;

FIG. 18 is an enlarged view of the region A in FIG. 6;

FIG. 19 is an enlarged view of the region B in FIG. 6;

FIGS. 20 to 25 are diagrams each illustrating a process step of a manufacturing method for a circuit substrate, in accordance with embodiments of the present disclosure; and

FIG. 26 is a flowchart of a detection method for a circuit substrate, in accordance with embodiments of the present disclosure.

### DETAILED DESCRIPTION

The technical solutions in some embodiments of the present disclosure will be described clearly and completely with reference to the accompanying drawings; however, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” are used for descriptive purposes only, and are not to be construed as indicating or implying a relative importance or implicitly indicating a number of indicated technical features. Thus, features defined by “first” or “second” may explicitly or implicitly include one or more of the features. In the description of the embodiments of the present disclosure, the term “a plurality of” or “multiple” means two or more unless otherwise specified.

In the description of some embodiments, the expressions “coupled,” “connected,” and derivatives thereof may be used. For example, the term “connected” may be used in the description of some embodiments to indicate that two or more elements are in direct physical or electrical contact with each other. As another example, the term “coupled” may be used in the description of some embodiments to indicate that two or more elements are in direct physical or electrical contact. However, the term “coupled” or “communicatively coupled” may also mean that two or more elements are not in direct contact with each other, but still cooperate or interact with each other. The embodiments disclosed herein are not necessarily limited to the contents herein.

The phrase “at least one of A, B, and C” has the same meaning as the phrase “at least one of A, B, or C”, both including the following combinations of A, B, and C: only A, only B, only C, a combination of A and B, a combination of A and C, a combination of B and C, and a combination of A, B, and C.

The phrase “A and/or B” includes the following three combinations: only A, only B, and a combination of A and B.

The use of the phrase “applicable to” or “configured to” herein means an open and inclusive expression, which does not exclude devices that are applicable to or configured to perform additional tasks or steps.

In addition, the use of the phrase “based on” or “according to” is meant to be open and inclusive, since a process, step, calculation, or other actions that are “based on” or “according to” one or more of the stated conditions or values may, in practice, be based on or according to additional conditions or values exceeding those stated.

The term such as “about,” “substantially,” and “approximately” as used herein includes a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°. and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views that are schematic illustrations of idealized embodiments. In the accompanying drawings, thicknesses of layers and areas of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a curved feature. Therefore, the regions shown in the accompanying drawings are schematic in nature, and their shapes are not intended to show actual shapes of the regions in a device, and are not intended to limit the scope of the exemplary embodiments.

At present, light-emitting substrates including numbers of Mini LEDs have been applied in the high-end electronic sports and other industries for their high contrast ratio and fast response characteristics. However, for a light-emitting substrate of 27 inches or above (e.g., 27 inches or 32 inches) having more than 10,000 Mini LEDs, poor soldering of any one of these Mini LEDs may result in defects in the light-emitting substrate. Therefore, how to quickly detect the soldering of each Mini LED (e.g., the soldering of each pin of each Mini LED) will be a decisive factor affecting the stability of the quality of the light-emitting substrate.

FIG. 1 is a partial top view of a light-emitting substrate provided in the related art.

Referring to FIG. 1, the light-emitting substrate 100A in the related art includes a base substrate 10A, a plurality of connection groups 20A provided on the base substrate 10A, and Mini LEDs 30A connected (e.g., soldered) to the connection groups 20A, where FIG. 1 shows one of the connection groups 20A. The connection group 20A may include two conductive patterns, the conductive patterns may serve as pads. An anode (i.e., a pin) of the Mini LED 30A is connected (e.g., soldered) to one of the conductive patterns, and a cathode (i.e., the other pin) of the Mini LED 30A is connected (e.g., soldered) to the other conductive pattern. In order to ensure the soldering effect and to facilitate the detection of the soldering effect, the area of an individual conductive pattern is greater than the area of an orthographic projection of the Mini LED 30A on the base substrate 10A.

A manufacturing method for the light-emitting substrate 100A may include the following steps that: first, a solder paste is formed on the connection group 20A, for example, a stencil (hereinafter referred to as a first stencil, such as a stainless stencil) may be utilized to print the solder paste on the connection group 20A; and then, the Mini LED 30A is soldered to the connection group 20A through the solder paste. Since the conductive patterns each have a relatively large area, so a portion (hereinafter referred to as an exposed portion) of each conductive pattern necessarily extends beyond the contour of the Mini LED 30A as seen from the top view. Therefore, it is possible to determine whether the soldering between each conductive pattern and a corresponding pin of the Mini LED 30A is good by detecting the extent to which the exposed portion of each conductive pattern has been wet with solder paste.

In order to avoid the solder paste electrically connecting different conductive patterns, the solder paste is required to be strictly printed onto individual conductive patterns without being allowed to extend beyond the contours of these conductive patterns, which requires the first stencil to have a high fabrication precision. However, for a light-emitting substrate 100A of more than 20 inches, it is difficult for a corresponding first stencil to have a high fabrication precision due to the relatively large size of the light-emitting substrate 100A, which results in the printed solder paste being misaligned with the conductive patterns, which may cause different conductive patterns to be electrically connected by the solder paste, thereby reducing the yield of the light-emitting substrate 100A. Moreover, limited by the production precision of the first stencil, the first stencil has a relatively small thickness, resulting in a short service life thereof.

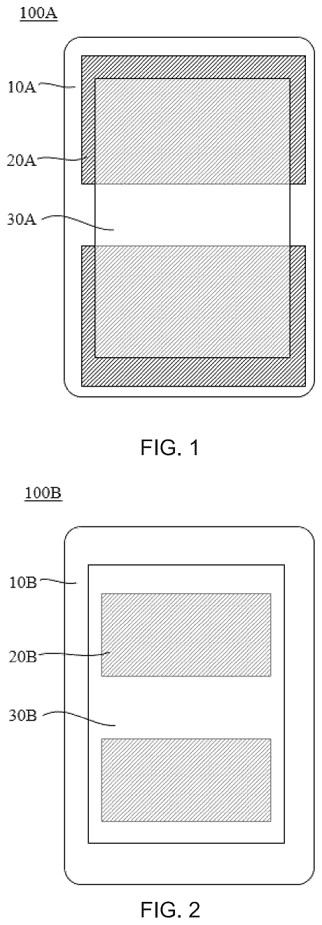

In order to solve the above problem, embodiments of the present disclosure provide a light-emitting substrate. FIG. 2 is a partial top view of the light-emitting substrate provided in the embodiments of the present disclosure.

Referring to FIG. 2, a light-emitting substrate 100B, having a size of, for example, more than 20 inches, may include a base substrate 10B, a plurality of connection groups 20B provided on the base substrate 10B, and Mini LEDs 30B connected (e.g., soldered) to the connection groups 20B, where FIG. 2 shows one of the connection groups 20B. The Mini LED 30B itself has bumps. A material of the bumps is a solder material, and the Mini LED 30B can be connected to the connection group 20B through the bumps.

A manufacturing method for the light-emitting substrate 100A may include the following steps that: first, a solder flux is applied onto the connection group 20B, for example, a second stencil (e.g., a stainless stencil) may be utilized to print the solder flux on the connection group 20B; and then, the bumps of the Mini LED 30B are soldered to the connection group 20B with the solder flux utilizing a reflow soldering process. Since the solder flux is made of a non-conductive material (i.e., an insulating material), the solder flux, even when lapped between different conductive patterns, will not cause the short-circuiting problem in those conductive patterns. Therefore, the solder flux is allowed to extend beyond contours of individual conductive patterns, e.g., a pattern formed by the solder flux can extend from one conductive pattern to another conductive pattern. In this way, the precision requirement for printing the solder flux is significantly lower than the precision requirement for printing the solder paste, which means that the fabrication precision of the second stencil is lower than the fabrication precision of the first stencil. In this way, the second stencil may have a relatively large thickness, thereby improving the service life thereof. As a result, it is possible to make the Mini LED 30B align accurately with conductive patterns, resulting in a high yield of the light-emitting substrate 100B.

However, due to the limited volume of the individual Mini LED 30B (i.e., the limited mass of the soldering material constituting the bumps), a portion of the individual conductive pattern that is wet by the melted bumps has a relatively small area when the Mini LED 30B is soldered to the connection group 20B. Understandably, the conductive pattern is required to be wet as much as possible in order to ensure the soldering effect, however, the limited soldering material that comes with the Mini LED 30B restricts the area of the individual conductive pattern from being made larger. In general, the total area of the connection group 20B is less than the area of the Mini LED 30B. In this case, in a case of detecting the soldering effect of Mini LEDs 30B with connection groups 20B, each conductive pattern in a connection group 20B is completely covered by a corresponding Mini LED 30B, leaving no point sites for detecting the soldering, resulting in an impossibility to detect the extent to which each conductive pattern is wet by the melted bumps and to determine whether the conductive pattern is well soldered to the Mini LED 30A.

To solve the above problems, embodiments of the present disclosure provide an electronic apparatus. The electronic apparatus has the function of displaying images, which include still images or moving images, where the moving images may be a video. For example, the electronic apparatus may be any of, but is not limited to, a displayer, a television, a billboard, a digital photo frame, a laser printer with display function, a telephone, a cell phone, a personal digital assistant (PDA), a digital camera, a portable camcorder, a viewfinder, a navigator, a large-area wall, a home appliance, an information query device (e.g., business query devices for e-government, banks, hospitals, electricity, etc.), a monitor, an electronic picture screen, a virtual reality (VR) display device, an augmented reality (AR) display device, and a vehicle-mounted display.

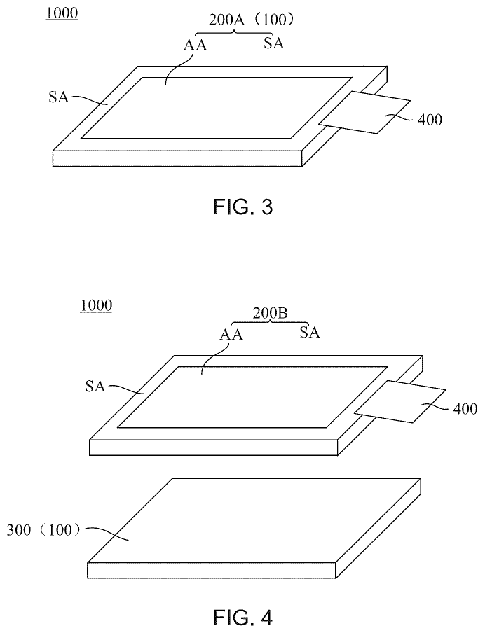

FIG. 3 is a structural diagram of an electronic apparatus provided in embodiments of the present disclosure.

In some embodiments, referring to FIG. 3, the electronic apparatus 1000 may include a display panel 200A (the display panel 200A hereinafter may also be referred to as a circuit substrate 100), which may be, for example, a self-luminous display panel. The display panel 200A has a display region AA and a non-display region SA, in which the display region AA is a region of the display panel 200A for displaying images, and the non-display region SA is a region of the display panel 200A other than the display region AA. The non-display region SA may be located on at least one side (e.g., one side or more sides) of the display region AA. For example, the non-display region SA may be provided around the display region AA in periphery.

The display panel 200A may be any one of an organic light-emitting diode (OLED) display panel, a quantum dot light-emitting diode (QLED) display panel, and a diminutive light-emitting diode (Mini LED or Micro LED) display panel. Accordingly, the display panel 200A includes a plurality of light-emitting elements located in the display region AA. As the name suggests, the light-emitting element is an electronic device capable of emitting light, such as an OLED, a QLED, or a diminutive LED.

The electronic apparatus 1000 may further include at least one (e.g., any one or more than one) of structures such as a frame and a circuit board 400, where the circuit board 400 may be a flexible printed circuit (FPC) or a printed circuit board (PCB). The circuit board 400 may be coupled to the display panel 200A and configured to transmit electrical signals to the display panel 200A. In addition, both the display panel 200A and the circuit board 400 may be mounted into a space enclosed by the frame.

FIG. 4 is a structural diagram of another electronic apparatus provided in embodiments of the present disclosure.

In some other embodiments, referring to FIG. 4, the electronic apparatus 1000 may include a display panel 200B and a light-emitting substrate 300 (the light-emitting substrate 300 hereinafter may also be referred to as a circuit substrate 100). The display panel 200B may be a liquid crystal display (LCD) panel. The display panel 200B has a display region AA and a non-display region SA. The light-emitting substrate 300 is provided on the back side of the display panel 200B and is configured to provide a backlight to the display panel 200B. The electronic apparatus 1000 may further include film sheets provided on a light-exit side of the light-emitting substrate 300, and light passing through the film sheets has a more uniform brightness and is directed to the display panel 200B. The light-emitting substrate 300 may include a plurality of light-emitting elements, which can be referred to as described above.

The electronic apparatus 1000 may further include at least one of structures such as a frame and a circuit board 400. The specific structures may be referred to in connection with the description of the electronic apparatus 1000 illustrated in FIG. 3 and will not be repeated herein.

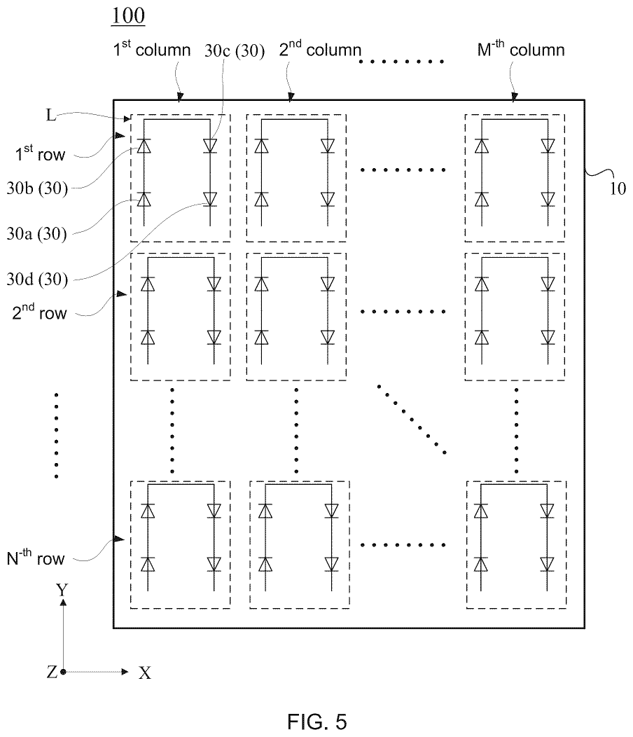

FIG. 5 is a circuit diagram of a circuit substrate provided in embodiments of the present disclosure.

To facilitate the following description, an X-Y-Z coordinate system is established. The first direction X and the second direction Y intersect and are both parallel to a plane, i.e., an X-Y plane, where the circuit substrate 100 is located. For example, the first direction X and the second direction Y are perpendicular to each other; and the third direction Z is a thickness direction of the circuit substrate 100, where the third direction Z is perpendicular to the X-Y plane.

Referring to FIG. 5, the circuit substrate 100 includes a base substrate 10 and at least one (e.g., one or more than one) light-emitting unit L provided on the base substrate 10.

The base substrate 10 may be set for actual requirements. For example, the base substrate 10 may be a rigid base substrate, a material of which may be glass or polymethyl methacrylate (PMMA). Alternatively, the base substrate 10 may be a flexible base substrate, a material of which may be polyethylene terephthalate (PET), polyethylene naphthalate two formic acid glycol ester (PEN), ultra-thin glass, or polyimide (PI). As another example, the base substrate 10 may be a composite plate with thermally conductive properties, such as a composite plate made from a material with a high flame retardant level. The composite plate may further have insulating properties, for example, it may be a flame retardant level 4 (FR-4) epoxy resin-glass cloth laminate. As another example, the base substrate 10 may also be made of a thermally conductive material. The thermally conductive material may be a non-metallic thermally conductive material having good insulating properties, such as PI.

Although a finite number of light-emitting units L are shown in FIG. 5, the number of the plurality of light-emitting units L is not limited. In some embodiments, the plurality of light-emitting units L may be arranged in an array, for example, arranged in N rows and M columns, where N is an integer greater than 0 and M is an integer greater than 0. For example, N≥2 and M≥2. In some other embodiments, the plurality of light-emitting units L may be arranged in any other design manner, such as in accordance with a desired display pattern, without being limited to a matrix arrangement.

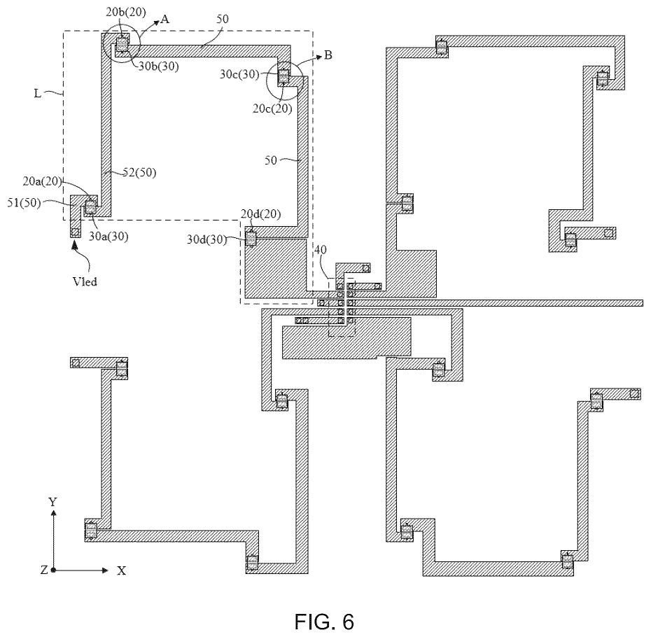

FIG. 6 is a partial top view of a circuit substrate provided in embodiments of the present disclosure.

Referring to FIG. 6, a plurality of traces 50 are provided on the base substrate 10. The material of the traces 50 is a metal material capable of using for soldering, for example, copper (Cu), copper-tin/stannum (Cu—Sn) alloy, copper-manganese (Cu—Mn) alloy, or the like. A protective layer (not shown in FIG. 6) is provided on the plurality of traces 50. The protective layer has a plurality of openings formed, for example, by an etching process. The openings each expose a portion of a trace 50, the portion serving as a conductive pattern. Thus, a contour of the lower edge of the opening (i.e., an edge proximate to the base substrate 10) and the conductive pattern have the identical shape. The material of the protective layer is an insulating material, which may include at least one of silicon nitride, silicon oxide, or the like, or may also include other suitable materials. The protective layer may be a single-layer structure or a multilayer structure. For example, the multilayer structure may be a double-layer structure consisting of a silicon oxide layer and a silicon nitride layer stacked on top of each other.

A (e.g., each) light-emitting unit L includes at least one (e.g., one or more than one) connection group 20 and at least one (e.g., one or more than one) electronic device 30.

The connection groups 20 each include multiple conductive patterns, such as two, three, or four. That is to say, the connection groups 20 are portions of the plurality of traces 50. An electronic device 30 is connected (e.g., soldered) to a connection group 20. The number of connection groups 20 and the number of electronic devices 30 in a light-emitting unit L may be the same, such as one, two, or four; and the connection groups 20 and the electronic devices 30 may be soldered in one-to-one correspondence. Exemplarily, referring to FIG. 6, a light-emitting unit L includes four connection groups 20a, 20b, 20c, and 20d, and four electronic devices 30a, 30b, 30c, and 30d corresponding to these four connection groups 20 respectively. In this light-emitting unit L, these electronic devices 30 are connected together by multiple traces 50 where the four connection groups 20 are located, thereby causing these electronic devices 30 to be connected in series. In addition, in this light-emitting unit L, these electronic devices 30 may be distributed in an array, but of course, they may also be distributed in other forms, such as in a circular array, as required.

The connection groups 20 are provided on the base substrate 10. Exemplarily, two of multiple conductive patterns of a connection group 20 are a first conductive pattern and a second conductive pattern.

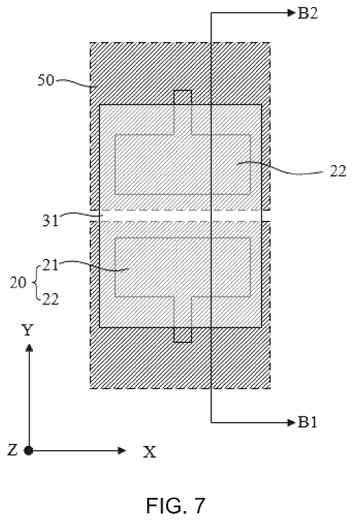

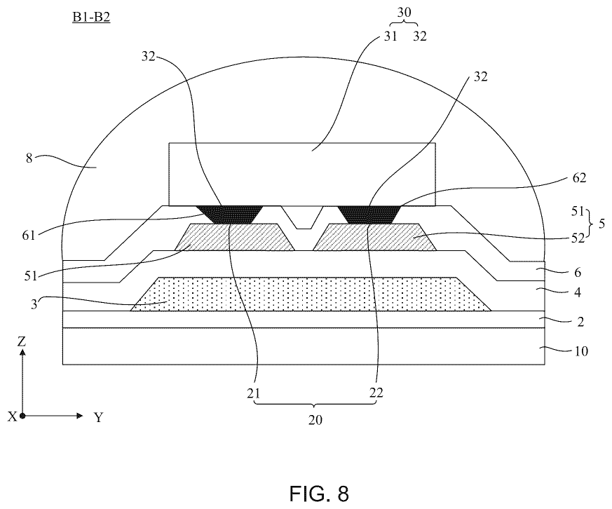

FIG. 7 is a partial top view of a circuit substrate provided in embodiments of the present disclosure. FIG. 8 is a cross-sectional view taken along the section line B1-B2 of FIG. 7.

Referring to FIGS. 7 and 8, the connection groups 20 are provided on the base substrate 10. Exemplarily, multiple conductive patterns of a connection group 20 are a first conductive pattern 21 and a second conductive pattern 22, in which one of the first conductive pattern 21 and the second conductive pattern 22 is an anode and the other is a cathode. For example, the first conductive pattern 21 is a cathode and the second conductive pattern 22 is an anode.

The electronic device 30 is soldered to the connection group 20, and may be a light-emitting element. The light-emitting element is an element that emits light when powered on. The electronic device includes a chip 31 and multiple bumps 32 provided on the chip 31.

The chip 31 may, for example, be an LED, such as a diminutive LED, an OLED, a QLED, or other light-emitting chips, without limitation herein. As an example, the chip 31 may be a diminutive light-emitting chip, and the size of the diminutive light-emitting chip may refer to the size of the diminutive LED. Here, the diminutive LED includes light-emitting diodes with sub-millimeter scale or even micrometer scale, and may further include light-emitting diodes of smaller size. The light-emitting diode with sub-millimeter scale is also referred to as a Mini LED, and the size (e.g., length) of the Mini LED may be 50 μm to 150 μm, such as 80 μm to 120 μm. The light-emitting diode with the micrometer scale is also referred to as a Micro LED, and the size (e.g., length) of the Micro LED may be less than 50 μm, such as 10 μm to 50 μm.

Solder (i.e., the solder material) is deposited on the chip 31 by a certain process and reflowed at a certain temperature to form metal solder balls, which are the bumps 32. The chip 31 is provided with multiple bumps 32, for example, two. The material (i.e., the solder) of the bumps includes a single metal or an alloy metal which have adhesive and conductive properties, such as tin/stannum (Sn), silver (Ag), copper (Cu), or gold (Au).

Each conductive pattern in the connection group 20 is soldered to at least one (e.g., one or more than one) bump 32. For example, the first conductive pattern 21 is soldered to one or two bumps 32, and the second conductive pattern 22 is soldered to one or two bumps 32.

The circuit substrate 100 includes a plurality of material layers provided in stack in a third direction Z, which are described below. Referring to FIG. 8, the circuit substrate 100 may include a first conductive pattern layer 5 and a protective layer 6, which are provided in sequence in stack on the base substrate 10. The first conductive pattern layer 5 is a layer in which the plurality of traces are located.

In embodiments of the present disclosure, the term “pattern layer” may be of a layer structure that includes specific patterns and is formed by performing a patterning process on at least one film layer, which is formed by using a same film forming process. Depending on different specific patterns, the patterning process may include several gluing, exposure, development or etching processes, and the specific patterns in the formed layer structure may be continuous or discontinuous, and these specific patterns may also be at different heights (or have different thicknesses).

The protective layer 6 covers the first conductive pattern layer 5 and includes a plurality of openings formed, for example, by an etching process. Portions of the first conductive pattern layer 5 exposed by the openings are each a conductive pattern, so the shape of a contour of the lower edge of the opening (i.e., an edge proximate to the base substrate 10) is the shape of the conductive pattern. Exemplarily, the plurality of openings includes first openings 61 and second openings 62, and portions of the first conductive pattern layer 5 exposed by the first openings 61 each serve as a first conductive pattern 21, and portions of the first conductive pattern layer 5 exposed by the second openings 62 each serve as a second conductive pattern 22. The first conductive pattern layer 5 may include a plurality of patterns, and the first openings 61 and the second openings 62 are located above different patterns.

In some embodiments, the circuit substrate 100 further includes a buffer layer 2 located between the base substrate 10 and the first conductive pattern layer 5. The buffer layer 2 may increase the attachment between the base substrate 10 and the layer above the buffer layer 2.

In some embodiments, referring to FIG. 8, the circuit substrate 100 further includes a second conductive pattern layer 3 located between the base substrate 10 and the first conductive pattern layer 5, and a first insulating layer 4 provided between the second conductive pattern layer 3 and the first conductive pattern layer 5. Along the third direction Z, an orthographic projection of the second conductive pattern layer 3 on the base substrate 10 covers orthographic projections of the conductive patterns on the base substrate 10. In this way, if a pin of an electronic device 30 protrudes a conductive pattern during placement of the electronic device 30, this conductive pattern will be connected to the second conductive pattern layer 3 below it without short-circuiting by connecting with another conductive pattern, thereby making the product more reliable. The first insulating layer 4 is provided between the first conductive pattern layer 5 and the second conductive pattern layer 3, preventing the first conductive pattern layer 5 and the second conductive pattern layer 3 from being directly connected, short-circuiting the electronic devices, and affecting the product yield.

Herein, an orthographic projection of an object covering an orthographic projection of another object means that the orthographic projection of that another object is within the orthographic projection of the aforementioned object.

In some embodiments, referring to FIG. 8, the circuit substrate 100 may further include a second insulating layer 8, which may cover the electronic devices 30, and may also cover a portion of the protective layer 6 located around the electronic devices 30. The second insulating layer 8 can seal the electronic devices 30, thereby isolating the electronic devices from external environment and avoiding erosion by water and oxygen in the external environment. In addition, portions of the second insulating layer 8 each above an electronic device (e.g., light-emitting element) 30 can form a convex lens, thereby converging light emitted by the electronic device 30.

Materials of the buffer layer 2, the protective layer 6, the first insulating layer 4 and the second insulating layer 8 are insulating materials, which can be found in the description above and will not be repeated herein. Here, the materials of these four may be the same or different. A material of each of the first conductive pattern layer 5 and the second conductive pattern layer 3 may be selected from metal single-element materials such as copper (Cu), aluminum (Al), molybdenum (Mo), titanium (Ti), chromium (Cr), and tungsten (W), or may be an alloy material constituting of at least two of the metal elements selected from described above, which will not be limited herein.

In some embodiments, continuing to FIG. 6, the circuit substrate 100 further includes driving elements 40. The driving elements 40 are provided on the base substrate 10. A (e.g., each) driving element 40 is connected to at least one (e.g., one or more than one) light-emitting unit L. Exemplarily, one driving element 40 is coupled to four light-emitting units L, configured to provide these light-emitting units L with respective required driving signals to drive electronic devices 30 in these light-emitting units L to operate. The driving element 40 may control respective brightness of individual light-emitting units L, and driving signals it provides to different light-emitting units L may be the same or different. For example, the driving element 40 may be a display driver integrated circuit (DDIC), which is configured to provide the light-emitting unit L with a driving signal and a relayed signal. For example, the relay signal is an address signal provided to another driving element, i.e., that another driving element receives the relay signal as an input signal, thereby obtaining the address signal. For example, the driving signal may be a driving current for driving the electronic device (e.g., the light-emitting element) in the light-emitting unit L to emit light.

In some embodiments, referring to FIG. 6, a light-emitting unit (e.g., each light-emitting unit) L further includes a driving voltage terminal Vied. The driving voltage terminal Vied is configured to provide a driving voltage, e.g., to provide a high voltage, for example, in a case where an electronic device 30 (which is provided as at least one in number, such as four) in the light-emitting unit L is required to emit light. Two ends of each light-emitting unit L are coupled to the driving voltage terminal Vied and the driving element, such that all of the electronic devices 30 in the light-emitting unit L may be connected in series.

Exemplarily, continuing to FIG. 6, each light-emitting unit L includes four connection groups 20a, 20b, 20c, and 20d, and four electronic devices 30a to 30d each corresponding to a respective connection group. Each connection group has a first conductive pattern as an anode and a second conductive pattern as a cathode. The four electronic devices are connected in series through their respective anodes and cathodes. The anode of the connection group 20a (i.e., the anode of the light-emitting unit located at one end thereof) is coupled to the driving voltage terminal Vied, and the cathode of the connection group 20d (i.e., the cathode of the light-emitting unit L at the other end thereof) is coupled to the driving element 40.

In another implementation, the connection group may be a driving chip connection group, and the electronic device may be a driving element. The driving element includes a driving chip and at least one bump provided on the driving chip. The structure and material of the bump of the driving chip and the driving element may be described with reference to the description of that of the conductive pattern and the bump of the electronic device above and will not be repeated herein.

In some embodiments, continuing to FIG. 6, multiple traces 50 are provided between the driving voltage terminal Vied and the driving element to connect more than one (e.g., four) connection groups 20 (e.g., the four connection groups 20a to 20d) in sequence (i.e., in series).

Referring to FIG. 6, the circuit substrate further includes first traces 51 and second traces 52. These first traces 51 and second traces 52 are provided on the base substrate 10. One first trace 51 connects the driving voltage terminal Vied to the anode of the connection group 20a at one end of the light-emitting unit, and one second trace 52 connects the cathode of the connection group 20a to the anode of the connection group 20b in the middle of the light-emitting unit. Another first trace 51 connects the cathode of the connection group 20b and the anode of the connection group 20c in the middle of the light-emitting unit, and another second trace 52 connects the cathode of the connection group 20c and the anode of the connection group 20d at the other end of the light-emitting unit. Yet another first trace 51 connects the cathode of the connection group 20c to the anode of the connection group 20d, and yet another second trace 52 connects the cathode of the connection group 20d to the driving element 40.

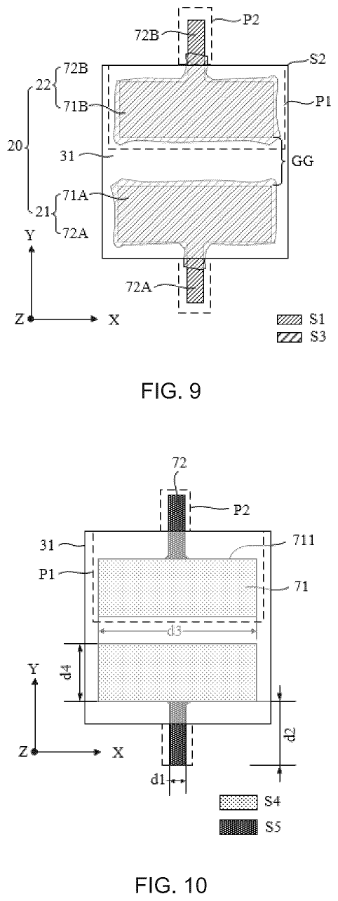

FIG. 9 is a partial top view of a circuit substrate provided in embodiments of the present disclosure.

Referring to FIG. 9, each conductive pattern includes a first portion P1 and a second portion P2 connected to each other. An orthographic projection of a chip 31 on the base substrate 10 covers an orthographic projection of the first portion P1 on the base substrate 10, and is non-overlapping with an orthographic projection of the second portion P2 on the base substrate 10. That is to say, of an orthographic projection of each conductive pattern of the connection group 20 on the base substrate 10, a portion occupied by the first portion P1 is covered by the orthographic projection of the chip 31 on the base substrate 10, and a portion occupied by the second portion P2 is located outside the orthographic projection of the chip 31 on the base substrate 10. In a case where a chip 31 is soldered to a connection group 20, a first portion P1 of each conductive pattern is wet by at least one (e.g., one) of molten bumps 32, and part or entire of the second portion P2 is also wet by the bump. The total area (denoted as S3) of a region wet by all the bumps 32 on the chip is greater than the total area of the first portions P1 of all the conductive patterns in the connection group 20.

The total area (denoted as S1) of multiple conductive patterns (e.g., all the conductive patterns in a connection group 20) connected to a chip 31 is less than the area (denoted as S2) of that chip 31. The total area S1 of the multiple conductive patterns may be the total area of orthographic projections of all of the conductive patterns of the connection group 20 on the base substrate 10. The area S2 of the chip is the area of the orthographic projection of the chip 31 on the base substrate 10. Since the bump 32 has limited solder, when the bump 32 is soldered to the connection group 20, the area S3 of the region where the molten bump 32 is capable of wetting is limited and less than the area S2 of the chip 31. Therefore, in order to make the molten bump 32 capable of wetting the entire connection group 20 corresponding to the electronic device 30 having the bump 32, the total area S1 of the multiple conductive patterns connected to the chip 31 is less than the area S2 of the chip.

In some examples, if a conductive pattern in a circuit substrate 100 is soldered to a bump 32, the circuit substrate 100 may be designed in such a way as to obtain a pre-estimated wetting area (denoted as Sc) by dividing the volume (denoted as Vb) of the bump before soldering by the height (denoted as H1) of the bump after soldering. Here, subject to the limitations of process of fabricating the bump, there exists that Vb=S*H2, where S is the area of a pin in the chip that is required to carry the bump (the bump is required to be fabricated on that pin in order to be connected, e.g., contacted, to that pin), and H2 is the maximum height of the bump that is capable of being fabricated (e.g., 25 μm). The height H1 of the bump after soldering is the height of the bump in the fabricated circuit substrate 100, which may take a value in a range of 6 μm to 10 μm, inclusive. For example, the height H1 may be 6 μm, 7 μm, 8 μm, 9 μm or 10 μm. The conductive pattern may be designed based on the pre-estimated wetting area Sc obtained above. For example, the area of the conductive pattern may be equal to or less than the pre-estimated wetting area Sc.

In the circuit substrate 100 provided by embodiments of the present disclosure, although the conductive pattern is relatively small due to the limitation of the size of the bump, it is possible to make a conductive pattern include a first portion P1 and a second portion P2 by adjusting the shape of the conductive pattern. The first portion P1 of the conductive pattern is blocked by the chip 31 (i.e., in a top-down view at an angle along the third direction Z, the chip 31 is able to block a portion of the conductive pattern, which is the first portion P1), and is used to be soldered to the chip 31 by the bump 32 to ensure soldering effect. The second portion P2 of the conductive pattern extends beyond the contour of the chip 31 and extends from below the chip 31 (i.e., the second portion P2 of the conductive pattern is not blocked by the chip 31 in the top-down view at the angle along the third direction Z). Therefore, the second portion P2 of the conductive pattern serves as a point site for detecting the soldering effect. By detecting the extent to which the second portion P2 is wet by the molten bump 32, the soldering effect of the conductive pattern to the chip is determined, and thus the soldering effect of the electronic device 30 to the connection group 20 is determined.

FIG. 10 is a structural diagram of a connection group provided in embodiments of the present disclosure.

In some embodiments, referring to FIG. 10, the conductive pattern includes a body portion 71 and at least one (e.g., one or more than one) extension portion 72, in which soldering is done mainly on the body portion 71. The body portion 71 has a first edge 711 parallel to the first direction X. The extension portion 72 protrudes the body portion 71 from the first edge 711.

A first dimension d1 of the extension portion 72 (hereinafter referred to as the width of the extension portion) is a dimension of the extension portion 72 in a direction parallel to the first edge 711. The length of the first edge 711 of the body portion 71 is d3. The width d1 of the extension portion 72 is less than the length d3 of the first edge 711. Since the area S3 of a region where the molten bump 32 is capable of wetting is limited, the total area S1 of conductive patterns in a connection group 20 is certain. The magnitude of the area S4 of the body portion 71 of the conductive pattern determines, to a great extent, the soldering effect of the electronic device 30 to the connection group 20. Under this premise, since the width d1 of the extension portion 72 is less than the length d3 of the first edge 711, the area S5 of the extension portion 72 of the conductive pattern is relatively small so that the area S4 of the body portion 71 can be larger, and the soldering of the electronic device 30 to the connection group 20 is stronger. This further improves the soldering of the circuit substrate while realizing the detection of the circuit substrate.

At least a portion (e.g., a portion or the entire) of an orthographic projection of the body portion 71 on the base substrate 10 is covered by an orthographic projection of the chip 31 on the base substrate 10, which ensures that the soldering of the chip 31 to the conductive pattern is effective. At least a portion (e.g., a portion or the entire) of an orthographic projection of the extension portion 72 on the base substrate 10 is located outside the orthographic projection of the chip 31 on the substrate 10. In this way, the aforementioned second portion P2 of the conductive pattern includes at least a portion of the extension portion 72. For example, the second portion P2 includes a portion of the extension portion 72, and this portion of the extension portion 72 can serve as a detection point site in this case; and the rest of the extension portion 72 (i.e., the other portion thereof) is blocked by the chip 31 and is able to function as a soldering with the chip 31. In this way, once the chip 31 has an assembly error in along the second direction Y (i.e., the chip 31 is slightly shifted along the second direction Y on the basis of FIG. 10), the body portion 71 of the conductive pattern is still able to be covered by the chip 31 and does not extend beyond the contour of the chip 31. As a result, the soldering effect is ensured and the area of the second portion P2 of the conductive pattern does not change significantly, reducing the adverse effects on the process of detecting the quality of the soldering. As another example, the second portion P2 includes the extension portion 72 and a portion of the body portion 71, and the extension portion 72 and the portion of the body portion 71 serve as a detection point site in this case.

In a case where a chip 31 is soldered to a connection group 20 in a standard position, the center of an orthographic projection of the connection group 20 on the base substrate is at the same position as the center of an orthographic projection of the chip 31 on the base substrate. Specifically, referring to FIG. 9, the first conductive pattern 21 is covered by the chip 31 to the same extent as the second conductive pattern 22 is covered by the chip 31. Exemplarily, continuing to FIG. 9, the body portion 71A of the first conductive pattern 21 and the body portion 71B of the second conductive pattern 22 are each fully covered by the chip 31, and the extension portion 72A of the first conductive pattern 21 and the extension portion 72B of the second conductive pattern 22 are covered by the chip 31 to the same extent. In this case, a portion of the extension portion 72A of the first conductive pattern 21 and a portion of the extension portion 72B of the second conductive pattern 22, which are not covered by the chip 31, can each serve as a detection point site.

In some embodiments, the extension portions of the conductive patterns have the same shape. In a case where the shift generated by soldering the chip 31 to the connection group 20 is only in the extension portions, since the extension portions have the same structure, an offset of the portion, not covered by the chip 31, of the extension portion 72A of the first conductive pattern 21 is compensated by an offset of the portion, not covered by the chip 31, of the extension portion 72B of the second conductive pattern 22, such that the area of a region, exposed by the bumps, of the connection group 20 remains unchanged, and the total area of portions, not covered by the chip 31, of all extension portions of the conductive patterns also remains unchanged.

FIG. 11 is a diagram illustrating a structure formed by an electronic device that has a shift during soldering, provided in embodiments of the present disclosure.

Referring to FIG. 11, when the soldering between the chip 31 and the connection group 20 is shifted, the center of the orthographic projection of the connection group 20 on the base substrate is not at the same position as the center of the orthographic projection of the chip 31 on the base substrate. Specifically, the first conductive pattern 21 is covered by the chip 31 to a different extent than the second conductive pattern 22 is covered by the chip 31. Exemplarily, the chip 31 is shifted in the second direction Y from the connection group 20. The body portion 71B of the second conductive pattern 22 is covered by the chip 31; and of the extension portion 72B of the second conductive pattern 22, a portion is covered by the chip 31 and the other portion extends beyond the contour of the chip 31. Of the body portion 71A of the first conductive pattern 21, a portion is covered by the chip 31 and the other portion extends beyond the contour of the chip 31; and the entire extension portion 72A of the first conductive pattern 21 extends beyond the contour of the chip 31. In this way, the portion, not covered by the chip 31, of the extension portion 72B of the second conductive pattern 22 can serve as a detection point site of the second conductive pattern 22; and the portion, not covered by the chip 31, of the body portion 71A of the first conductive pattern 21 can serve, with the extension portion 72A of the first conductive pattern 21, as a detection point site of the first conductive pattern 21.

In some embodiments, continuing to FIG. 10, a second dimension d2 of the extension portion 72 (hereinafter referred to as the length of the extension portion) is a dimension of the extension portion 72 in a direction perpendicular to the first edge 711. The maximum length d2 of the extension portion 72 is greater than a dimension d4 of the body portion 71 in the second direction Y (hereinafter referred to as the length of the body portion 71). In a case where the conductive pattern has a certain area, the greater the length d2 of the extension portion 72, the longer a portion of the extension portion 72 that extends beyond the contour of the chip 31, so that the length of the portion capable of serving as a detection point site is increased, which facilitates the detection of the soldering effect of the electronic device and the connection group.

In some embodiments, continuing to FIG. 9, the total area S1 of conductive patterns (e.g., all of the conductive patterns) in a connection group 20 is less than the difference between the area S2 of the chip 31 and the area of a conductive pattern gap GG covered by the chip 31, where the conductive pattern gap GG is a gap between adjacent body portions. Thus, the total area S1 of the conductive patterns is smaller. The first conductive pattern 21 and the second conductive pattern 22 are two adjacent conductive patterns, for example, an anode conductive pattern and a cathode conductive pattern, respectively. There exists a gap retained between the anode conductive pattern and the cathode conductive pattern, which is the conductive pattern gap GG. When the chip 31 is soldered to the connection group 20, the chip 31 covers the conductive pattern gap GG in addition to covering partial of the first conductive pattern 21 and partial the second conductive pattern 22. The difference between the area S2 of the chip 31 and the area of the conductive pattern gap GG covered by the chip 31 is greater than the total area of the first conductive pattern 21 and the second conductive pattern 22. Thus, the area of the first conductive pattern 21 and the area of the second conductive pattern 22 are smaller. Even so, the first conductive pattern 21 and the second conductive pattern 22 still each retain a respective detection site. In these embodiments of the present disclosure, the total area S1 of the conductive patterns is smaller on the basis of retaining the detection point sites.

In some embodiments, referring to FIG. 9, the first conductive pattern 21 and the second conductive pattern 22 are adjacent conductive patterns. Each extension portion 72A of the first conductive pattern 21 is located on a side, away from the body portion 71B of the second conductive pattern 22, of the body portion 71A of the first conductive pattern 21; and each extension portion 72B of the second conductive pattern 22 is located on a side, away from the body portion 71A of the first conductive pattern 21, of the body portion 71B of the second conductive pattern 22. That is, the extension portions of the first conductive pattern 21 and the second conductive pattern 22 are away from the conductive pattern gap GG. Each extension portion of a conductive pattern is away from the conductive pattern gap GG between the other conductive pattern opposite thereto, preventing short-circuiting of electronic devices due to lapping between the extension portions.

In some other implementations, the first conductive pattern 21 and the second conductive pattern 22 are two of conductive patterns of the connection group 20, and a gap between adjacent body portions of the conductive patterns is a conductive pattern gap GG. Exemplarily, the connection group 20 includes four conductive patterns that are provided two-by-two opposite to each other, with the conductive pattern gap GG between the conductive patterns. The extension portion of each conductive pattern extends away from the conductive pattern gap GG and extends beyond the edge of the body portion.

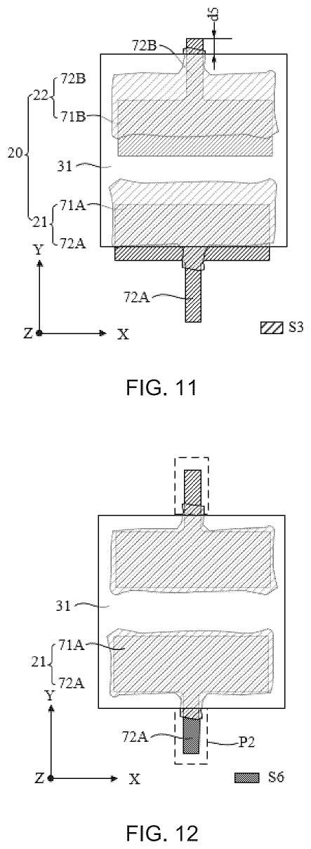

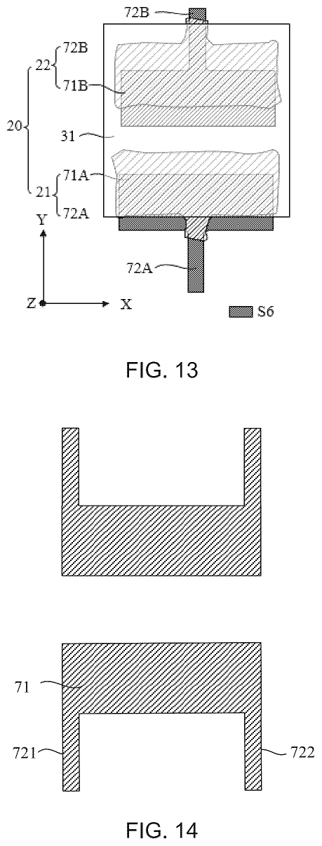

FIG. 12 is a partial top view of a circuit substrate provided in embodiments of the present disclosure. FIG. 13 is a partial top view of another circuit substrate provided in embodiments of the present disclosure.

In some embodiments, a ratio of the area (denoted as S6) of a portion, exposed by bumps, of the conductive pattern to a reference area is less than or equal to 10%, where the reference area is the total area of portions, belonging to the second portion P2, of all of the extension portions of the conductive pattern. That is to say, the ratio of the area of the portion, not wet by the bumps, of the conductive pattern to the area of portions, extending beyond the contour of the chip 31, of all of the extension portions in the conductive pattern is less than (and may be equal to) 10%, which means that the electronic device is soldered well to the connection group. If the ratio is greater than 10%, it means that the wettability of the bumps is poor, the conductive pattern is not well soldered, and repair treatment is required, otherwise the product yield will be affected.

Exemplarily, referring to FIG. 12, in a case where the chip 31 is soldered to the connection group in a standard position, a portion of the first conductive pattern 21 that is not wet by the bumps is a portion of the extension portion, and the area of the second portion P2 is the above reference area. If the ratio of the portion, not wet by the bumps, of the first conductive pattern to the area of the second portion P2 is less than 10%, it means that the first conductive pattern is poorly wet by the bumps, and repair treatment such as re-soldering is required.

As another example, referring to FIG. 13, when the chip 31 is shifted when soldered to the connection group 20, the chip 31 covers a portion of the body portion 71A of the first conductive pattern 21, and the bumps wet a portion of the body portion 71A of the first conductive pattern 21 and a portion of the extension portion 72A of the first conductive pattern 21. Of the body portion 71A of the first conductive pattern 21, the portion wet by the bumps is different from the portion covered by the chip 31. Therefore, the area S6 of a portion, exposed by the bumps, of the first conductive pattern 21 is equal to the difference between the area of a portion, not covered by the chip 31, of the body portion 71A and the area of a portion, not covered by the chip 31 but wet by the bumps, of the body portion 71A. In some examples, the reference area is the area of the extension portion 72A of the first conductive pattern 21.

For the connection group 20, referring to FIG. 13, the chip 31 covers the body portion 71B of the second conductive pattern 22 and a portion of the extension portion 72B of the second conductive pattern 22, and the bumps wet a portion of the body portion 71B of the second conductive pattern 22 and a portion of the extension portion 72B of the second conductive pattern 22. Since the body portion 71B of the second conductive pattern 22 is covered by the chip 31, only a portion of the extension portion 72B can be exposed. Thus, for the connection group 20, the reference area is the sum of the area of the extension portion 72A of the first conductive pattern 21 and the area of the portion, not covered by the chip 31, of the extension portion 72B of the second conductive pattern 22.

In some embodiments, the body portion 71 is in the shape of a polygon, with the first edge 711 being one edge of the polytope. For example, continuing to FIG. 10, the body portion 71 is in the shape of a rectangle, with the first edge 711 being a long side of the rectangle. An another example, the body portion 71 is the shape of a rectangle, with the first edge 711 being a short side of the rectangle. The first edge 711 is parallel to the first direction X, i.e., the extension portion protrudes from the long side of the rectangle. Since body portions of the two conductive patterns are provided opposite each other, the first edge of each body portion is located on a side of that body portion away from the conductive pattern gap. If a shift is generated the soldering of the electronic device 30 (e.g., the chip 31) to the connection group 20, and the shift occurs along the first direction X, referring to FIG. 13, since the extension portion protrudes from the long side of the rectangle away from the conductive pattern gap, even if each conductive pattern is provided with a single extension portion on a long side of the body portion thereof, the conductive pattern has a protruding portion capable of acting as a detecting point site.

In a case where the first edge 711 is a short side of a rectangle, if a conductive pattern has a single extension portion, and a shift occurs along the first direction X, only one side can provide a protruding portion acting as a detecting point site, and the other side can only be used with the body portion as a detection point site. However, if covered by the electronic device, the body portion does not serve the purpose of detection, and then it is only possible to provide extension portions on both short sides of the rectangle.

FIG. 14 is a structural diagram of another connection group provided in embodiments of the present disclosure.

In some embodiments, extension portions of each conductive pattern in a connection group may have the same shape or different shapes. For example, in a connection group, an extension portion of a first conductive pattern is in the shape of a rectangle and an extension portion of a second conductive pattern is in the shape of a circle cut by rectangle. As another example, an extension portion of a first conductive pattern is in the shape of a rectangle and an extension portion of a second conductive pattern is also in the shape of a rectangle.

The shape of each extension portion of a conductive pattern may be the same or different. For example, referring to FIG. 14, the first conductive pattern includes a first extension portion 721 and a second extension portion 722, with the first extension portion 721 being in the shape of a rectangle and the second extension portion 722 also being in the shape of a rectangle. As another example, the first conductive pattern includes a first extension portion 721 and a second extension portion 722, with the first extension portion 721 being in the shape of a rectangle and the second extension portion 722 being in the shape of an ellipse cut by rectangle. The extension portions may also be in other shapes, and the embodiments are not limited thereto.

In some embodiments, along a protruding direction of an extension portion, the width of the extension portion is the same at all positions. If the shift occurring in the soldering of the chip and the connection group is only in the extension portion, the area (i.e., the reference area) of portions, not covered by the chip, of all the extension portions in the conductive pattern has a small range of change, and does not change abruptly due to a relatively small shift. For example, the following situation will not occur: the range is first less than 10%, and then changes abruptly to greater than 10% after a relatively small shift occurs, resulting in the sharp change in the value making the detection result also change abruptly and the detection result is inaccurate. Exemplarily, continuing to FIG. 12, the extension portion 71A of the first conductive pattern 21 is in the shape of a rectangle, with uniform width. If the shift occurring in the soldering of the chip and the connection group is only in the extension portion, the reference area does not change by a large amount due to the uniform width of the extension portion, resulting in a small amount of change in the ratio of the area (denoted as S6) of the portion, not covered by the bumps, of the extension portion 72A of the first conductive pattern 21 to the reference area, and a more accurate detection result.

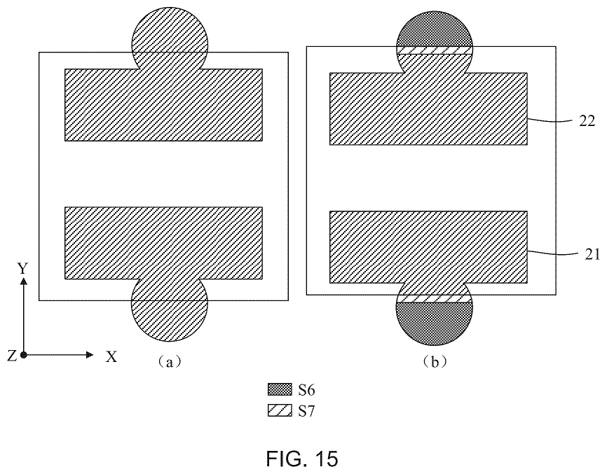

FIG. 15 is a structural diagram of yet another connection group provided in embodiments of the present disclosure.

In some embodiments, along a protruding direction of an extension portion, the width of the extension portion increases and then decreases. Exemplarily, referring to (a) in FIG. 15, an extension portion 71A of the first conductive pattern 21 is in the shape of a circle cut by rectangle, and the width of the extension portion 71A increases and then decreases along its protruding direction. Referring to (b) in FIG. 15, the shift occurring in the soldering of the chip and the connection group is only in the extension portion. In this case, a section (hereinafter referred to as a change section), caused by the shift, in the portion, not covered by the chip, of the extension portion accounts for a small ratio of the portion, not covered by the chip, of the extension portion; and even if the change in the area S7 of the change section changes by a large amount, it has a small effect on the change in the reference area. In this way, the change in the ratio of the area S6 of the portion, not covered by the bumps, of the extension portion 72A of the first conductive pattern 21 to the reference area is small, and the detection accuracy is improved.

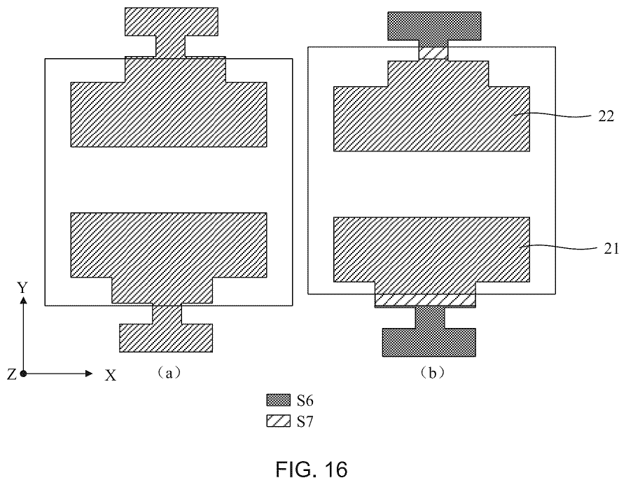

FIG. 16 is a structural diagram of still another connection group provided in embodiments of the present disclosure.

In some embodiments, along a protruding direction of an extension portion, the width of the extension portion decreases and then increases. Exemplarily, referring to (a) in FIG. 16, an extension portion 71A of the first conductive pattern 21 is in a shape of a capital letter I, and the width of the extension portion 71A decreases and then increases along its protruding direction. Referring to (b) in FIG. 16, the shift occurring in the soldering of the chip and the connection group is only in the extension portion. In this case, for the first conductive pattern 21, the amount of change in the area S7 of the change section is large, but the ratio of the area S7 of the change section to the entire portion, not covered by the chip, of the extension portion is small, and therefore the range of change in the reference area of the first conductive pattern 21 is small, such that the change in the ratio of the area S6 of the portion, not covered by the bumps, of the extension portion 72A of the first conductive pattern 21 to the reference area is small. For the second conductive pattern 22, the amount of change in the area S7 of the change section is small, and therefore the range of change in the reference area of the second conductive pattern 22 is small, such that the change in the ratio of the area of the portion, not covered by the bumps, of the extension portion of the second conductive pattern 22 to the reference area is small.

In some other embodiments, along a protruding direction of an extension portion, the width of the extension portion gradually decreases or gradually increases.

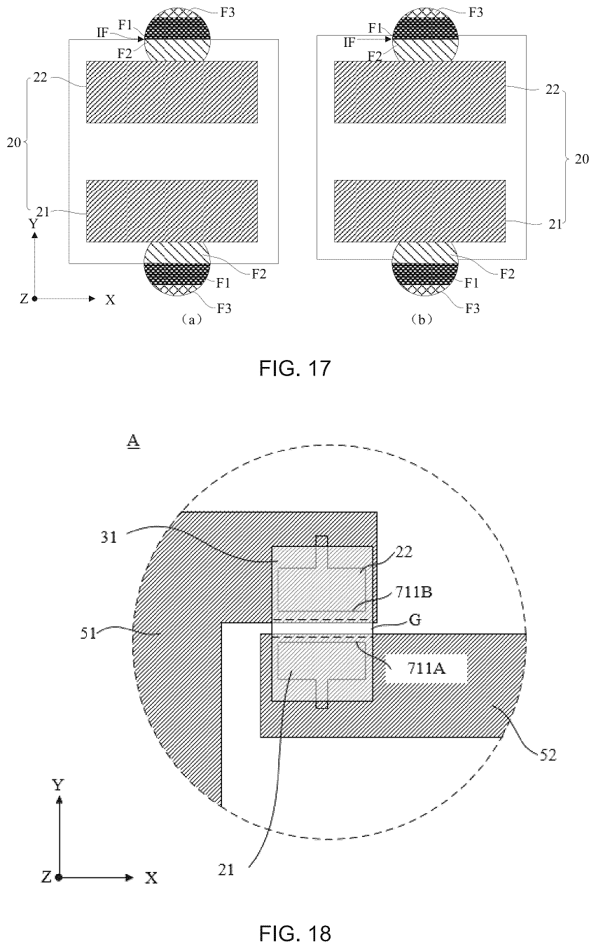

FIG. 17 is a structural diagram of still yet another connection group provided in embodiments of the present disclosure.

In some embodiments, referring to FIG. 17, an extension portion of a conductive pattern includes a first sub-portion F1, a second sub-portion F2, and a third sub-portion F3 that is the remaining portion not covered by the chip 31. The first sub-portion F1 and the second sub-portion F2 are axisymmetric figures, and have a demarcation line IF parallel to the first edge. In a case where the chip 31 is soldered to the connection group 20 in a standard position, the demarcation line IF is in the same line as one side of the contour of the chip 31. Exemplarily, the chip 31 covers respective second sub-portions F2 of the first conductive pattern 21 and the second conductive pattern 22. When the chip 31 is shifted in the second direction Y, the chip 31 covers a section of the first sub-portion F1 and the second sub-portion F2 of the second conductive pattern 22. When soldering of the connection group 20 is performed in the standard position, the reference area of the first conductive pattern 21 is the sum of the areas of its first and third sub-portions F1 and S3, and the reference area of the second conductive pattern 22 is the sum of the areas of its first and third sub-portions F1 and F3. When a shift occurs, the reference area of the first conductive pattern 21 becomes the sum of the areas of its first sub-portion F1, its third sub-portion F3, and a section of its second sub-portion F2, and the reference area of the second conductive pattern 22 becomes the sum of the areas of its third sub-portion F3 and a section of its first sub-portion F1. Since the first sub-portion F1 and the second sub-portion F2 in the same extension portion are axisymmetric figures, an increased portion of the reference area of the first conductive pattern 21 (i.e., a portion of the second sub-portion F2 that is shifted) has the same area as a decreased portion of the reference area of the second conductive pattern 22 (i.e., a portion of the first sub-portion F1 that is shifted), when the soldering position is shifted. In other words, when the shift occurs during soldering the electronic device with the connection group 20, the reference area of the entire connection group does not change. In this case, for the entire connection group, the ratio of the area of a region, exposed by the bumps, in the connection group to its reference area remains unchanged, which is conducive to improving the efficiency of detecting soldering effects of the connection group and the electronic device.

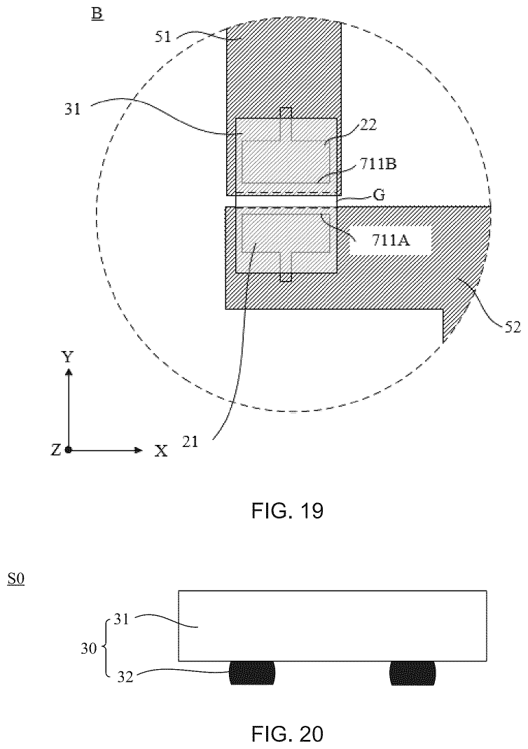

FIG. 18 is an enlarged view of the region A in FIG. 6. FIG. 19 is an enlarged view of the region B in FIG. 6.

The first trace 51 and the second trace 52 are provided therebetween with a trace gap G that is covered by the chip. A first edge of the first conductive pattern 21 is parallel to an extension direction of the trace gap G; and/or a first edge of the second conductive pattern 22 is parallel to the extension direction of the trace gap G.

For example, referring to FIG. 18, the first conductive pattern 21 is located in a section of the second trace 52, and an extension direction of the first edge 711A of the first conductive pattern 21 and an extension direction of this section of the second trace 52 are both in the first direction X. The second conductive pattern 22 is located in a section of the first trace 51, and an extension direction of the first edge 711B of the second conductive pattern 22 and an extension direction of this section of the first trace 51 are both in the first direction X. The extension direction of the trace gap G is also in the first direction X, which is parallel to the first edge 711A of the first conductive pattern 21 and the first edge 711B of the second conductive pattern 22.

As another example, referring to FIG. 19, the first conductive pattern 21 is located in a section of the second trace 52, and an extension direction of the first edge 711A of the first conductive pattern 21 and an extension direction of this section of the second trace 52 are both in the first direction X. The second conductive pattern 22 is located in a section of the first trace 51, and an extension direction of the first edge 711B of the second conductive pattern 22 in the second direction Y and perpendicular to an extension direction of this section of the first trace 51. The extension direction of the trace gap G is in the first direction X, which is parallel to the first edge 711A of the first conductive pattern 21 and the first edge 711B of the second conductive pattern 22.

As yet another example, the first edge of the first conductive pattern 21 is parallel to the extension direction of the trace gap, and the first edge of the second conductive pattern 22 is perpendicular to the extension direction of the trace gap.

As still yet another example, the first edge of the first conductive pattern 21 is perpendicular to the extension direction of the trace gap, and the first edge of the second conductive pattern 22 is parallel to the extension direction of the trace gap.

In these embodiments, the first edge of the conductive pattern is parallel to the extension direction of the trace gap, and the extension portion protrudes from the first edge, so that the first trace and/or the second trace in these embodiments can have a relatively large width, i.e., the cross-sectional area of the first trace and/or the second trace can be designed to be large. According to the law of resistance, R=ρL/S, it is known that the larger the cross-sectional area of the trace, the smaller the resistance. Therefore, the trace in these embodiments has a lower resistance, higher electrical performance, and the manner of designing the connection of traces is simple, which is easy to produce and fabricate.

In some embodiments, the circuit substrate may include a base substrate, connection groups, and electronic devices. The connection groups are provided on the base substrate and each include multiple conductive patterns, such as two, three, or four. The electronic devices each include a chip and multiple bumps provided on the chip. A conductive pattern is connected to at least one of the bumps of the chip. The conductive pattern includes a first portion and a second portion connected to each other. An orthographic projection of the chip on the base substrate covers an orthographic projection of the first portion on the base substrate and non-overlapping with an orthographic projection of the second portion on the base substrate. The total area of conductive patterns connected to the chip is less than an area of the chip.

In some examples, the circuit substrate may further include a protective layer that is provided on the connection groups. The protective layer is provided with openings each exposing a conductive pattern. In some other examples, the circuit substrate may further include traces that are provided on the base substrate. The connection groups are provided on the traces, and a layer in which the connection groups are located is electrically connected to the traces. The materials of the protective layer and the trace can be found in the description above and will not be repeated herein.

In the circuit substrate provided in the embodiments of the present disclosure, the conductive pattern is not completely covered by the chip and is divided into the first portion and the second portion. The first portion is covered by the chip for soldering to the chip by the bump to ensure soldering effect; while the second portion is not covered by the chip, i.e., beyond the contour of the chip, to serve as a detection point site for detecting the soldering effect. By detecting the extent to which the second portion is wet by the melted bump, the soldering effect of the second portion with the chip is determined, and thus the soldering effect of the electronic device with the conductive pattern is detected and determined.

FIGS. 20 to 25 are diagrams each illustrating a process step of a manufacturing method for a circuit substrate, in accordance with some embodiments.

Embodiments of the present disclosure provide a manufacturing method for a circuit substrate, which includes the following steps S0 to S5.

In S0, an electronic device is provided.

Referring to FIG. 20, multiple bumps 32 are provided on one side of a chip 31 of an electronic device 30. the bumps 32 of the electronic device 30 are reflowed and melted by a reflow equipment, which reflows the bumps 32 of the electronic device 30 so that the bumps 32 of the electronic device 30 become arcuate bumps; and then, the arcuate bumps are polished so that the lower end surfaces of all the bumps 32 are located at the same horizontal plane. The material of the bumps 32 can be found in the description above and will not be repeated herein.

In some embodiments, a solder material is utilized to form bumps 32 on a chip 31 to obtain an electronic device 30. The solder material includes a plurality of solder particles. The width d1 (refer to FIG. 10) of the extension portion 72 is greater than or equal to twice the average diameter of the plurality of solder particles of a bump. Alternatively, the width d1 (refer to FIG. 10) of the extension portion 72 is greater than or equal to twice the maximum diameter of the plurality of solder particles. Exemplarily, the material of the bump is tin/stannum (Sn) with a particle diameter of 10 μm, then the width d1 of the extension portion 72 is at least 20 μm, e.g., 20 μm, 25 μm, or 30 μm. If the width d1 of the extension portion 72 is less than twice the diameter of the plurality of solder particles, then, the bump can only be in the form of particle (e.g., spherical particle) and the width of the extension portion 72 can only accommodate a single spherical particle. Since the spherical particles are difficult to be soldered to the conductive pattern, this results in the bump not being able to wet the extension portion 72, which affects detection.

As another example, it is possible to purchase electronic devices that are each self-contained with bumps 32.

In S1, a plurality of traces are formed on a base substrate.

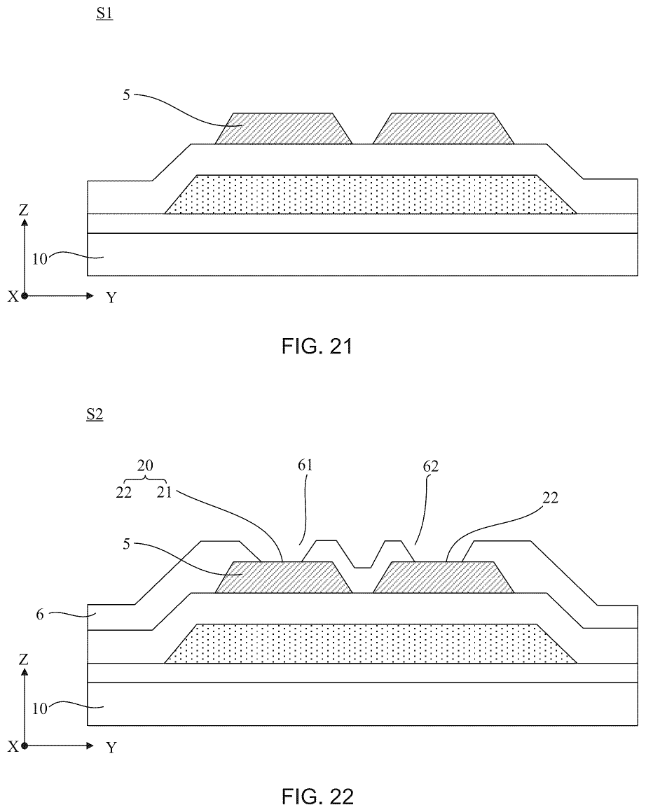

Referring to FIG. 21, a first conductive pattern layer 5 is formed on a base substrate 10, the first conductive pattern layer 5 being a layer in which the plurality of traces are located. The material of the first conductive pattern layer 5 can be found in the description above and will not be repeated here.

In S2, a protective layer is formed.

Referring to FIG. 22, the protective layer 6 covers the first conductive pattern layer 5. First openings 61 and second openings 62 are formed in the protective layer 6 by an etching process, exposing portions of the first conductive pattern layer 5. A portion of the first conductive pattern layer 5 exposed by a first opening 61 is a first conductive pattern 21, and a portion of the first conductive pattern layer 5 exposed by a second opening 62 is a second conductive pattern 22. The first conductive pattern 21 and the second conductive pattern 22 constitute a connection group 20. The material of the protective layer 6 can be found in the description above and will not be repeated here.

The conductive pattern includes a body portion and at least one extension portion. The body portion has a first edge. The at least one extension portion protrudes the body portion from the first edge of the body portion. The extension portion has a first dimension less than a length of the first edge, the first dimension of the extension portion being a dimension of the extension portion in a direction parallel to the first edge.

In S3, a solder flux layer is formed on a side of a plurality of conductive patterns away from the base substrate.

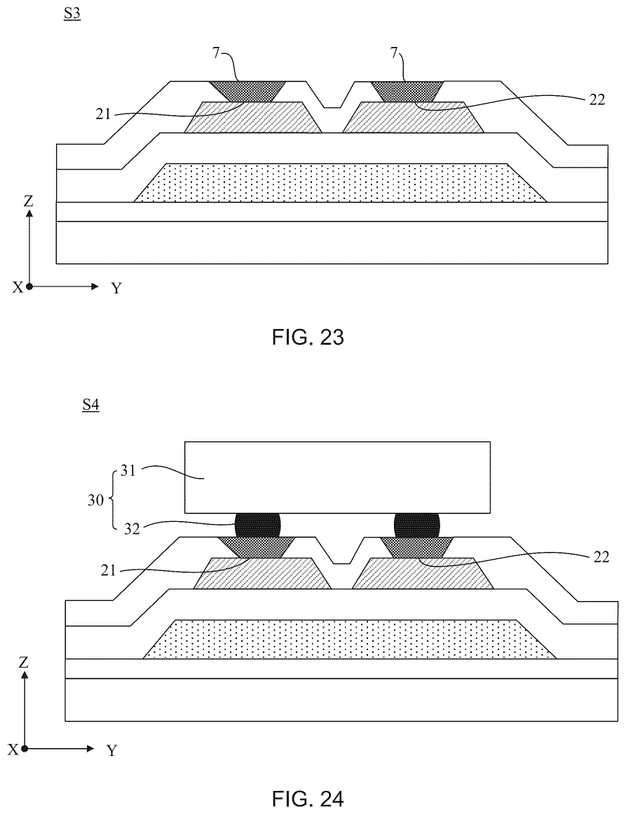

Referring to FIG. 23, a solder flux layer 7 is formed on the first conductive pattern 21 and the second conductive pattern 22.

The solder flux layer 7 is capable of assisting and facilitating the soldering process in a reflow soldering process, while providing protection, blocking oxidation reactions, and the like. The material of the solder flux layer may be an insulating material, such as one or a combination of more of a rosin resin and its derivatives, a synthetic resin surfactant, an organic acid activator, and the like, but is not limited thereto.

In S4, an electronic device is placed on the solder flux layer.

Referring to FIG. 24, the bumps 32 face the first conductive pattern 21 and the second conductive pattern 22 so that the electronic device 30 is capable of being connected to the connection group in a subsequent step. In this case, the conductive pattern includes a first portion and a second portion connected to each other; an orthographic projection of the chip 31 on the base substrate 10 covers an orthographic projection of the first portion on the base substrate 10, and is non-overlapping with an orthographic projection of the second portion on the base substrate 10; and the total area of conductive patterns that are to be connected to the chip 31 is less than the area of the chip.

In some embodiments, a ratio of a length of the first edge to a dimension of the bump 32 in a direction parallel to a direction in which the first edge is located, prior to placement of the electronic device 30 above the conductive patterns, is in a range of 1 to 1.3, inclusive, such as 1, 1.2, or 1.3. The length of the first edge is the width of the conductive pattern, and the width of the conductive pattern is greater than the dimension of the bump in the direction where the first edge is located, allowing the bump to be in full contact with the conductive pattern through the opening, and not allowing the solder of the bump to come into contact with other portions of the circuit substrate. In this way, the solder can be fully applied so that the solder is fully wet on the conductive pattern, which in turn increases the wettable area of the bump.

In S5, the circuit substrate is formed.

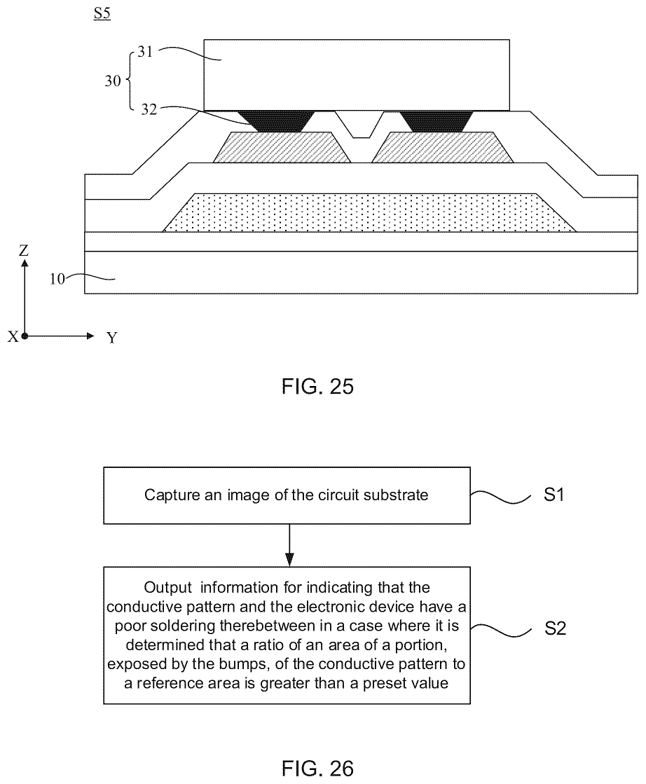

Referring to FIG. 25, at least one bump 32 on the chip 31 is connected to the conductive pattern by heat treatment. Exemplarily, the electronic device 30 is reflowed with the conductive pattern, and during the reflow process, the bump 32 melts, wetting the connection group, and the bump 32 is soldered to the conductive pattern under the action of the solder flux layer 7, soldering the chip 31 to the base substrate 10. After the reflow process, substantially all of the solder flux layer 7 evaporates or reacts away. In some embodiments, it is also possible to remove the residual solder flux layer 7. e.g., by utilizing chemical reagents such as alcohol, acetone, ethanol, or the like for cleaning.

In the circuit substrate formed in these embodiments, the total area of conductive patterns corresponding to a chip is less than the area of this chip, and a conductive pattern is partly covered by the chip and partly protrudes beyond a contour of the chip, which facilitates the detection of the soldering effect of the electronic device and the connection group.

FIG. 26 is a flowchart of a detection method for a circuit substrate, in accordance with some embodiments.

Embodiments of the present disclosure provide a detection method for a circuit substrate, as shown in FIG. 26, including the following steps S1 and S2.

In S1, an image of the circuit substrate is collected.

The image of the circuit substrate is captured from a side of the electronic device away from the base substrate using an inspection equipment, such as an automated optical inspection (AOI) equipment. The image shows at least one detection point site.

In S2, in a case where it is determined that a ratio of an area of a portion, exposed by the bumps, of the conductive pattern to a reference area is greater than a preset value, information is output, which is used for indicating that the conductive pattern and the electronic device have a poor soldering therebetween.

The area of the portion of the conductive pattern that is exposed by the bumps is the area of the portion of the conductive pattern that is not covered by the bumps. The reference area is the total area of portions of all extension portions of the conductive pattern that belong to the second portion. The ratio of the area of the portion of the conductive pattern not covered by the bumps to the reference area is calculated. The preset value is set to, for example, 10%, 15%, or 20%. The calculated ratio of the area of the portion of the conductive pattern not covered by the bumps to the reference area is compared with the preset value. If the ratio is greater than the preset value, it indicates that the conductive pattern in the connection group is poorly soldered to the electronic device, and information about the poor soldering is output in preparation for the next step of the repair work. If the ratio is less than (or equal to) the preset value, the information that the connection group is well-soldered to the electronic device may be output, or the next step may proceed directly.

Exemplarily, the portion of the conductive pattern that is not covered by the chip is a detection point site, in which the portion that is covered by the bumps exhibit a silver-gray metallic color and the portion that is not wet by the bumps exhibit a yellow color. The detection equipment calculates the ratio of the portion of the conductive pattern not wet by the bumps to the reference area. If the ratio is less than 10%, the connection group is well soldered to the electronic device. If the ratio is greater than 10%, the connection group is not well-soldered to the electronic device, and information about poor soldering will be output.

In some embodiments, a length of a portion of the extension portion of the conductive pattern that belongs to the second portion is greater than or equal to a minimum detectable dimension to improve detection accuracy of the inspection equipment. Continuing to refer to FIG. 11, the portion of the conductive pattern that protrudes beyond the contour of the chip 31 is the extension portion, and the extension portion has the length d5 that is at least equal to the minimum detectable dimension. Exemplarily, the length d5 of the extension portion of the second conductive pattern 22 is greater than or equal to the minimum detectable dimension. If the length d5 of the extension portion is less than the minimum detectable dimension, the following may occur: if the ratio of the area of the portion of the conductive pattern exposed by the bumps to the reference area is greater than the preset value, the inspection equipment should output the information that the soldering is poor. However, since the length d5 of the extension portion is less than the minimum detectable dimension, the inspection equipment fails to detect the dimension therein, then when calculating the ratio of the areas, the area of the portion of the conductive pattern that is not covered by the bumps is considered to be 0, and the area of the portion belonging to the second portion of the conductive pattern of all of the extension portions is also considered to be 0. With 0 being less than the preset value, the inspection equipment assumes that the electronic device is well soldered to the connection group, resulting in the existence of a number of poorly soldered electronic devices in the circuit substrate, affecting the product yield.

The foregoing description is only specific embodiments of the present disclosure, but the scope of protection of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

What is claimed is:

1. A circuit substrate, comprising:
a base substrate; and
a plurality of traces, provided on the base substrate;
a protective layer, provided on the plurality of traces, the protective layer having a plurality of openings each exposing a portion of a trace, the portion serving as a conductive pattern; and
an electronic device, including a chip and multiple bumps provided on the chip;
wherein the conductive pattern is connected to at least one of the bumps on the chip; the conductive pattern includes a first portion and a second portion connected to each other; an orthographic projection of the chip on the base substrate covers an orthographic projection of the first portion on the base substrate, and is non-overlapping with an orthographic projection of the second portion on the base substrate; and a total area of multiple conductive patterns connected to the chip is less than an area of the chip.

2. The circuit substrate according to claim 1, wherein the conductive pattern includes:
a body portion, having a first edge; and
at least one extension portion, protruding the body portion from the first edge, wherein an extension portion has a first dimension less than a length of the first edge, the first dimension of the extension portion being a dimension of the extension portion in a direction parallel to the first edge;
wherein the orthographic projection of the chip on the base substrate covers at least a portion of an orthographic projection of the body portion on the base substrate, and is non-overlapping with at least a portion of an orthographic projection of the extension portion on the base substrate.

3. The circuit substrate according to claim 2, wherein
the first portion includes at least a portion of the body portion whose orthographic projection on the base substrate is covered by the orthographic projection of the chip on the base substrate; and
the second portion includes at least a portion of the extension portion whose orthographic projection on the base substrate is non-overlapping with the orthographic projection of the chip on the base substrate.

4. The circuit substrate according to claim 2, wherein a total area of the at least one extension portion is less than an area of the body portion.

5. The circuit substrate according to claim 2, wherein the extension portion has a maximum second dimension greater than a dimension of the body portion in a direction perpendicular to the first edge, the second dimension of the extension portion being a dimension of the extension portion in the direction perpendicular to the first edge.

6. The circuit substrate according to claim 2, wherein the body portion is in a shape of a rectangle, with the first edge being a long side of the rectangle.

7. The circuit substrate according to claim 2, wherein
along a protruding direction of the extension portion, the first dimension of the extension portion is same at all positions; or
along the protruding direction of the extension portion, the first dimension of the extension portion increases and then decreases; or
along the protruding direction of the extension portion, the first dimension of the extension portion decreases and then increases.

8. The circuit substrate according to claim 7, wherein
the extension portion of the conductive pattern includes a first sub-portion and a second sub-portion, and the first sub-portion and the second sub-portion form axisymmetric figures, with a symmetry axis being a demarcation line between the first sub-portion and the second sub-portion, the demarcation line being parallel to the first edge.

9. The circuit substrate according to claim 2, wherein the total area of the multiple conductive patterns is less than a difference between the area of the chip and an area of a conductive pattern gap covered by the chip, the conductive pattern gap being a gap between adjacent body portions.

10. The circuit substrate according to claim 2, wherein
two of the multiple conductive patterns connected to the chip are a first conductive pattern and a second conductive pattern; each extension portion of the first conductive pattern is located on a side, away from a body portion of the second conductive pattern, of a body portion of the first conductive pattern; and each extension portion of the second conductive pattern is located on a side, away from the body portion of the first conductive pattern, of the body portion of the second conductive pattern.

11. The circuit substrate according to claim 2, wherein
the plurality of traces include a first trace and a second trace, the first trace and the second trace are provided therebetween with a trace gap that is covered by the chip, wherein
a first edge of a conductive pattern of the first trace is parallel to an extension direction of the trace gap, and/or a first edge of a conductive pattern of the second trace is parallel to the extension direction of the trace gap.

12. The circuit substrate according to claim 2, wherein a ratio of an area of a portion, exposed by the bumps, of the conductive pattern to a reference area is less than or equal to 10%, the reference area being an area of a portion, belonging to the second portion, of the at least one extension portion of the conductive pattern.

13. A circuit substrate, comprising:
a base substrate; and
a connection group, provided on the base substrate and including multiple conductive patterns; and
an electronic device, including a chip and multiple bumps provided on the chip;
wherein a conductive pattern is connected to at least one of the bumps on the chip; the conductive pattern includes a first portion and a second portion connected to each other; an orthographic projection of the chip on the base substrate covers an orthographic projection of the first portion on the base substrate, and is non-overlapping with an orthographic projection of the second portion on the base substrate; and a total area of multiple conductive patterns connected to the chip is less than an area of the chip.

14. An electronic apparatus, comprising the circuit substrate according to claim 1.

15. A manufacturing method for a circuit substrate, comprising:
forming a plurality of traces on a base substrate;
forming a protective layer, the protective layer covering the plurality of traces and formed with a plurality of openings each exposing a portion of a trace, the portion serving as a conductive pattern;
forming a solder flux layer on a side of a plurality of conductive patterns away from the base substrate;
placing an electronic device on the solder flux layer, the electronic device including a chip and multiple bumps provided on the chip, such that the conductive pattern faces at least one of the bumps, wherein the conductive pattern includes a first portion and a second portion connected to each other; an orthographic projection of the chip on the base substrate covers an orthographic projection of the first portion on the base substrate, and is non-overlapping with an orthographic projection of the second portion on the base substrate; and a total area of multiple conductive patterns that are to be connected to the chip is less than an area of the chip; and
performing heat treatment on the traces, the solder flux layer, and the electronic device to remove the solder flux layer, such that the at least one bump on the chip is connected to the conductive pattern.

16. The manufacturing method according to claim 15, wherein
the conductive pattern includes a body portion and at least one extension portion; the body portion has a first edge; the at least one extension portion protrudes the body portion from the first edge; and an extension portion has a first dimension less than a length of the first edge, the first dimension of the extension portion being a dimension of the extension portion in a direction parallel to the first edge, wherein
the orthographic projection of the chip on the base substrate covers at least a portion of an orthographic projection of the body portion on the base substrate, and is non-overlapping with at least a portion of an orthographic projection of the extension portion on the base substrate; and
a ratio of a length of the first edge to a reference dimension is in a range of 1 to 1.3, inclusive, the reference dimension being a dimension of the bump of the electronic device in a direction parallel to the first edge before placing the electronic device on the solder flux layer.

17. The manufacturing method according to claim 16, further comprising:
forming the bumps, using a solder material, on the chip to obtain the electronic device, the solder material including a plurality of solder particles;
wherein the first dimension of the extension portion is greater than or equal to twice an average diameter of the plurality of solder particles; or the first dimension of the extension portion is greater than or equal to twice a maximum diameter of the plurality of solder particles.

18. A detection method for a circuit substrate, the circuit substrate being the circuit substrate according to claim 2, and the detection method for the circuit substrate comprising:
capturing an image of the circuit substrate at a side of the electronic device away from the base substrate; and
in a case where it is determined that a ratio of an area of a portion, exposed by the bumps, of the conductive pattern to a reference area is greater than a preset value, outputting information for indicating that the conductive pattern and the electronic device have a poor soldering therebetween, the reference area being an area of a portion, belonging to the second portion, of the at least one extension portion of the conductive pattern.

19. The detection method according to claim 18, wherein
a second dimension of the portion, belonging to the second portion, of the at least one extension portion of the conductive pattern is greater than or equal to a minimum detectable dimension, the second dimension being a dimension of the portion in a direction perpendicular to the first edge.

20. A detection method for a circuit substrate, the circuit substrate being the circuit substrate according to claim 13, and the detection method for the circuit substrate comprising:
capturing an image of the circuit substrate at a side of the electronic device away from the base substrate; and
in a case where it is determined that a ratio of an area of a portion, exposed by the bumps, of the conductive pattern to a reference area is greater than a preset value, outputting information for indicating that the conductive pattern and the electronic device have a poor soldering therebetween, the reference area being an area of the second portion of the conductive pattern.
